(19) United States
(12) Patent Application Publication
(10) Pub. No.: US 2025/0318083 A1
(43) Pub. Date: Oct. 9, 2025

(54) HEAT DISSIPATION FILM AND ELECTRONIC DEVICE INCLUDING THE SAME

(71) Applicant: Samsung Electronics Co., Ltd., Suwon-si (KR)

(72) Inventors: Min PARK, Suwon-si (KR); Jihyeon SON, Suwon-si (KR); Yoonhee CHANG, Suwon-si (KR); Jieun HWANG, Suwon-si (KR); Jeonggen YOON, Suwon-si (KR); Jinhwan JUNG, Suwon-si (KR)

(21) Appl. No.: 19/174,404

(22) Filed: Apr. 9, 2025

Related U.S. Application Data
(63) Continuation of application No. PCT/KR2025/095091, filed on Mar. 25, 2025.

(30) Foreign Application Priority Data
Apr. 9, 2024 (KR) 10-2024-0048279
Jul. 15, 2024 (KR) 10-2024-0093128

(51) Int. Cl. H05K 7/20; H01Q 1/02

(52) U.S. Cl. CPC H05K 7/2039; H01Q 1/02

(57) ABSTRACT

An electronic device according to an embodiment of the disclosure may comprise a housing, a circuit board disposed in the housing, an antenna module disposed in the housing and including an antenna pattern portion electrically connected to the circuit board, and a heat dissipation film attached to the antenna module. The heat dissipation film may include a first layer formed of a conductive material, a second layer having a predetermined width to surround the antenna pattern portion and disposed on one surface of the first layer, and a third layer disposed on one surface of the second layer and formed of an insulating material. The second layer may be configured to be hydrogen-bonded with the first layer and covalently bonded with the third layer.

### CROSS-REFERENCE TO RELATED APPLICATIONS)

This application is a continuation application, claiming priority under 35 U.S.C. §365(c), of an International application No. PCT/KR2025/095091, filed on Mar. 25, 2025, which is based on and claims the benefit of a Korean patent application number 10-2024-0048279, filed on Apr. 9, 2024, in the Korean Intellectual Property Office, and of a Korean patent application number 10-2024-0093128, filed on Jul. 15, 2024, in the Korean Intellectual Property Office, the disclosure of each of which is incorporated by reference herein in its entirety.

### BACKGROUND

### Field

The disclosure relates to a heat dissipation film and an electronic device including the same.

### Description of Related Art

As electronics, information, or communication technology grows, an electronic device comes equipped with various functions. For example, smartphones may include the functions of a sound player, imaging device, and scheduler, as well as the communication function and, on top of that, may implement more various functions by having applications installed thereon. The electronic device may not only its equipped applications or stored files but also access, wiredly or wirelessly, a server or another electronic device to receive, in real-time, various pieces of information.

With increased degree of integration, electronic devices are able to perform various functions despite their reduced size. As the electronic device is highly integrated, a controlling component (e.g., a processor or communication module) or an electronic component (e.g., an antenna module) for wireless communication in the electronic device may become more compact or advanced. For example, as various electronic components become more advanced or integrated, may exert enhanced performance.

The electronic component or electronic device may exhibit stable operating performance in an appropriate temperature environment. However, integrated and advanced electronic components may generate heat while operating, causing deterioration of power efficiency or operating performance. Desktop computers, laptop computers, or such electronic devices may quickly cool down their internal space or self-heating electronic components (hereinafter, ‘heat generation components’) using a mechanical device, e.g., a cooling fan. However, it may be hard to equip small portable or wearable electronic devices with a cooling device.

A heat dissipation film with high thermal conductivity may be attached to, or disposed adjacent to, the surface of a heat generation component to cool (or heat-dissipate) the heat generation component. For a component coupled with an antenna among the heat generation components, the heat dissipation film may be formed of a material with heat thermal conductivity and insulation, considering the radiation properties of the antenna. For example, the heat dissipation film may be formed based on graphene fluoride. However, the graphene fluoride-based heat dissipation film may not secure uniform insulation because fluorine (F) atoms with insulation properties are unevenly bonded to the surface of the graphene when producing particles of graphene fluoride. Further, it is difficult to implement the film to a desired thickness due to strong brittleness caused by low bonding strength.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a heat dissipation film that is attachable to an antenna-coupled electronic component and has a patterned insulation area and an electronic device including the same.

Additional aspects will be set forth in part in the description which follows and, in part, will be apparent from the description, or may be learned by practice of the presented embodiments.

In accordance with an aspect of the disclosure, an electronic device may be provided. The electronic device may include a housing, a circuit board disposed in the housing, an antenna module disposed in the housing and including an antenna pattern portion electrically connected to the circuit board, and a heat dissipation film attached to the antenna module. The heat dissipation film may include a first layer formed of a conductive material, a second layer having a predetermined width to surround the antenna pattern portion and disposed on one surface of the first layer, and a third layer disposed on one surface of the second layer and formed of an insulating material. The second layer may be configured to be hydrogen-bonded with the first layer and covalently bonded with the third layer.

In accordance with another aspect of the disclosure, a heat dissipation film attached to an antenna module having an antenna pattern portion may be provided. The heat dissipation film may include a first layer formed of a conductive material, a second layer having a predetermined width to surround the antenna pattern portion and disposed on one surface of the first layer, and a third layer disposed on one surface of the second layer and formed of an insulating material. The second layer may be hydrogen-bonded with the first layer and covalently bonded with the third layer.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view illustrating an electronic device in a network environment according to various embodiment of the disclosure;

FIG. 2 is a front exploded perspective view illustrating an electronic device according to an embodiment of the disclosure;

FIG. 3 is a rear perspective view illustrating an electronic device according to an embodiment of the disclosure;

FIG. 4 is a front exploded perspective view illustrating an electronic device according to an embodiment of the disclosure;

FIG. 5 is a rear exploded perspective view illustrating an electronic device according to an embodiment of the disclosure;

FIG. 6 is a plan view illustrating a speaker module according to an embodiment of the disclosure;

FIG. 7 is a bottom view illustrating a speaker module according to an embodiment of the disclosure;

FIG. 8 is a perspective view illustrating a heat dissipation film according to an embodiment of the disclosure;

FIG. 9 is a cross-sectional view illustrating a heat dissipation film according to an embodiment of the disclosure;

FIG. 10 is an enlarged view illustrating an area of an antenna pattern portion of a speaker module as illustrated in FIG. 7 according to an embodiment of the disclosure;

FIG. 11A is a view illustrating a coupled structure of layers constituting a heat dissipation film according to an embodiment of the disclosure;

FIG. 11B is a view illustrating a coupled structure of layers constituting a heat dissipation film according to an embodiment of the disclosure;

FIG. 12 is a view illustrating a stacked structure of a heat dissipation film according to an embodiment of the disclosure;

FIG. 13 is a flowchart illustrating manufacturing a basic unit structure constituting a heat dissipation film according to an embodiment of the disclosure;

FIG. 14 is a flowchart illustrating manufacturing a heat dissipation film according to an embodiment of the disclosure;

FIG. 15 is a plan view illustrating an antenna according to an embodiment of the disclosure;

FIG. 16 is a front perspective view illustrating an electronic device according to an embodiment of the disclosure;

FIG. 17 is a rear plan view illustrating an electronic device according to an embodiment of the disclosure;

FIG. 18 is a partially exploded perspective view illustrating the electronic device of FIGS. 16 and 17 including a hinge device according to various embodiments of the disclosure;

FIG. 19 is a plan view illustrating a connector according to an embodiment of the disclosure;

FIGS. 20A and 20B are views illustrating a bonding force between particles constituting a heat dissipation film according to embodiments of the disclosure;

FIG. 21 is a graph illustrating a tensile stress of a heat dissipation film according to an embodiment of the disclosure; and

FIG. 22 is a graph illustrating a storage modulus of a heat dissipation film according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases.

The term “and/or” may denote a combination(s) of a plurality of related components as listed or any of the components.

As used herein, such terms as “1st” and “2nd,” or “first” and “second” may be used to simply distinguish a corresponding component from another, and does not limit the components in other aspect (e.g., importance or order).

As used herein, the terms ‘front surface,’ ‘rear surface,’ ‘upper surface,’ ‘side surface,’ ‘left side,’ ‘right side,’ ‘upper portion,’ and ‘lower portion’ are defined with respect to the drawings, and the shape and position of each component are not limited by the terms.

It will be further understood that the terms “comprise” and/or “have,” as used herein, specify the presence of stated features, integers, steps, operations, elements, and/or components, but do not preclude the presence or addition of one or more other features, integers, steps, operations, elements, components, and/or groups thereof.

It will be understood that when a component is referred to as “connected to,” “coupled to”, “supported on,” or “contacting” another component, the components may be connected to, coupled to, supported on, or contact each other directly or via a third component.

Throughout the specification, when one component is positioned “on” another component, the first component may be positioned directly on the second component, or other component(s) may be positioned between the first and second component.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an integrated circuit (IC), or the like.

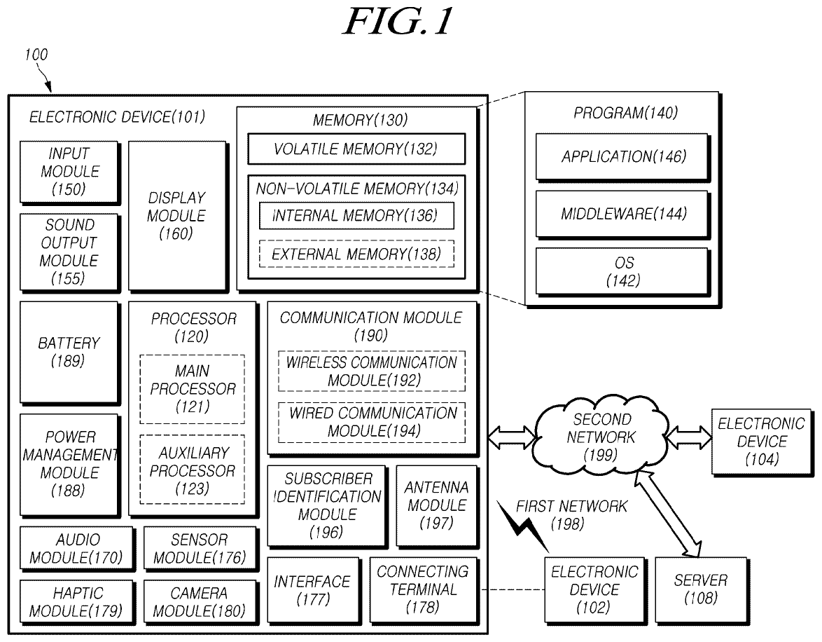

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a fifth generation (5G) network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mm Wave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

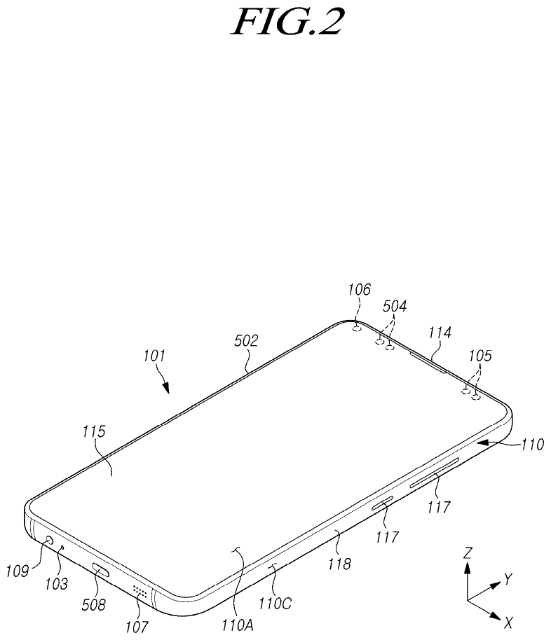

FIG. 2 is a front exploded perspective view illustrating an electronic device according to an embodiment of the disclosure.

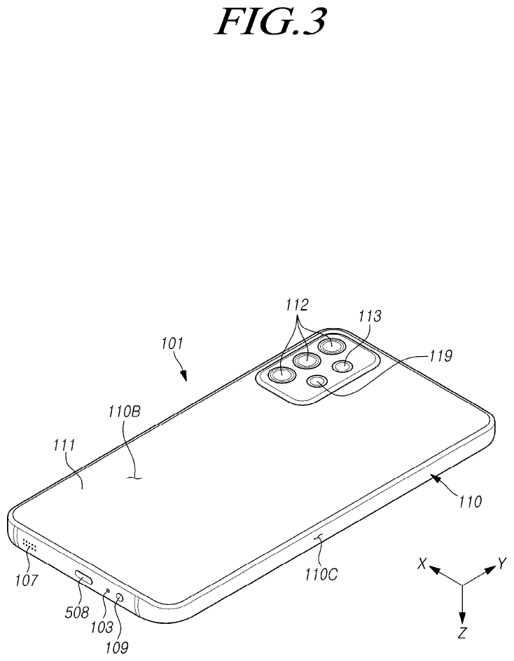

FIG. 3 is a rear perspective view illustrating an electronic device according to an embodiment of the disclosure.

The components of the electronic device 101 of FIGS. 2 and 3 may be identical in whole or part to the components of the electronic device 101 of FIG. 1.

Referring to FIGS. 2 and 3, according to an embodiment, an electronic device 101 (e.g., the electronic device 101 of FIG. 1) may include a housing 110 including a first surface (or front surface) 110A, a second surface (or rear surface) 110B, and a side surface 110C surrounding a space between the first surface 110A and the second surface 110B. According to an embodiment (not shown), the housing 110 may denote a structure forming the first surface 110A of FIG. 2, the second surface 110B of FIG. 3, and some of the side surfaces 110C.

According to an embodiment, at least part of the first surface 110A may have a substantially transparent front plate 502 (e.g., a glass plate or polymer plate including various coat layers). The second surface 110B may be formed of a substantially opaque rear plate 111. The rear plate 111 may be formed of, e.g., laminated or colored glass, ceramic, polymer, metal (e.g., aluminum, stainless steel (STS), or magnesium), or a combination of at least two thereof. The side surface 110C may be formed by a side structure (or a “side bezel structure”) 118 that couples to the front plate 502 and the rear plate 111 and includes a metal and/or polymer. In an embodiment, the rear plate 111 and the side structure 118 may be integrally formed together and include the same material (e.g., a metal, such as aluminum).

According to an embodiment, the front plate 502 may include area(s) that bend from at least a portion of an edge toward the rear plate 111 and seamlessly extend. For example, only one of the areas of the front plate 502 (or the rear plate 111), which bend to the rear plate 111 (or front plate 502) and extend may be included in one edge of the first surface 110A. According to an embodiment, the front plate 502 or rear plate 111 may be substantially flat and, in this case, may not include an area bending and extending. When an area bending and extending is included in the front plate 502 or rear plate 111, the thickness of the electronic device 101 at the portion including the area bending and extending may be smaller than the thickness of the rest.

According to an embodiment, the electronic device 101 may include at least one of a display 115, an audio module (e.g., the microphone hole 103, the external speaker hole 107, and the phone receiver hole 114), a sensor module (e.g., the first sensor module 504, the second sensor module (not illustrated), or the third sensor module 119), a camera module (e.g., the first camera device 105, the second camera device 112, or the flash 113), a key input device 117, a light emitting device 106, and a connector hole (e.g., the first connector hole 508 or the second connector hole 109). In an embodiment, the electronic device 101 may exclude at least one (e.g., the key input device 117 or the light emitting device 106) of the components or may add other components.

The display 115 may output a screen or be visually exposed through a significant portion of the first surface 110A (e.g., the front plate 502), for example. In an embodiment, at least a portion of the display 115 may be visually exposed through the front plate 502 forming the first surface 110A, or through a portion of the side surface 110C. In an embodiment, the edge of the display 115 may be formed to be substantially the same in shape as an adjacent outer edge of the front plate 502. In an embodiment (not illustrated), the interval between the outer edge of the display 115 and the outer edge of the front plate 502 may remain substantially even to give a larger area of visual exposure of the display 115.

According to an embodiment, a recess or an opening may be formed in a portion of the screen display area of the display 115, and there may be included at least one of an audio module (e.g., the phone receiver hole 114), a sensor module (e.g., the first sensor module 504), a camera module (e.g., the first camera device 105), and a light emitting device 106 that are aligned with the recess or the opening. In an embodiment (not shown), at least one of the audio module (e.g., the phone receiver hole 114), sensor module (e.g., the first sensor module 504), camera module (e.g., the first camera device 105), fingerprint sensor (not shown), and light emitting device 106 may be included on the rear surface of the screen display area of the display 115. In an embodiment (not illustrated), the display 115 may be disposed to be coupled with, or adjacent, a touch detecting circuit, a pressure sensor capable of measuring the strength (pressure) of touches, and/or a digitizer for detecting a magnetic field-type stylus pen.

According to an embodiment, the audio modules 103, 107, and 114 may include a microphone hole 103 and speaker holes (e.g., the external speaker hole 107 and the phone receiver hole 114). A microphone for acquiring external sounds may be disposed in the microphone hole 103. In an embodiment, a plurality of microphones may be disposed to detect the direction of the sound. The speaker holes may include an external speaker hole 107 and a phone receiver hole 114. According to an embodiment, the speaker holes (e.g., the external speaker hole 107 and the phone receiver hole 114) and the microphone hole 103 may be implemented as a single hole, or speakers may be included without the speaker holes (e.g., the external speaker hole 107 and the phone receiver hole 114) (e.g., piezo speakers).

According to an embodiment, the sensor module may generate an electrical signal or data value corresponding to an internal operating state or external environmental state of the electronic device 101. The sensor modules may include a first sensor module 504 (e.g., a proximity sensor) and/or a second sensor module (not shown) (e.g., a fingerprint sensor) disposed on the first surface 110A of the housing 110 and/or a third sensor module 119 disposed on the second surface 110B of the housing 110. The second sensor module (not shown) (e.g., a fingerprint sensor) may be disposed on the second surface 110B or side surface 110C as well as the surface 110A (e.g., the display 115) of the housing 110. The electronic device 101 may further include, e.g., at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor (e.g., first sensor module 504).

According to an embodiment, the camera modules may include a first camera device 105 disposed on the first surface 110A of the electronic device 101, and a second camera device 112 and/or a flash 113 disposed on the second surface 110B. The camera devices (e.g., the first camera device 105 and the second camera device 112) may include one or more lenses, an image sensor, and/or an image signal processor. The flash 113 may include, e.g., a light emitting diode or a xenon lamp. In an embodiment, one or more lenses (an infrared (IR) camera, a wide-angle lens, and a telephoto lens) and image sensors may be disposed on one surface of the electronic device 101. In an embodiment, flash 113 may emit infrared light. The infrared light emitted by the flash 113 and reflected by the subject may be received through the third sensor module 119. The electronic device 101 or the processor (e.g., the processor 120 of FIG. 1) of the electronic device 101 may detect depth information about the subject based on the time point when the infrared light is received from the third sensor module 119.

According to an embodiment, the key input device 117 may be disposed on the side surface 110C of the housing 110. In an embodiment, the electronic device 101 may exclude all or some of the above-mentioned key input devices 117 and the excluded key input devices 117 may be implemented in other forms, e.g., as soft keys, on the display 115. In an embodiment, the key input device may include the sensor module disposed on the second surface 110B of the housing 110.

According to an embodiment, the light emitting device 106 may be disposed on the first surface 110A of the housing 110, for example. The light emitting device 106 may provide, e.g., information about the state of the electronic device 101 in the form of light. In an embodiment, the light emitting device 106 may provide a light source that interacts with, e.g., the camera module (e.g., the first camera device 105). The light emitting device 106 may include, e.g., a light emitting diode (LED), an infrared (IR) LED, or a xenon lamp.

According to an embodiment, the connector holes (e.g., the first connector hole 508 or the second connector hole 109) may include, e.g., a first connector hole 508 for receiving a connector (e.g., a USB connector) for transmitting/receiving power and/or data to/from an external electronic device (e.g., the electronic device 102 of FIG. 1) and/or a second connector hole 109 (e.g., an earphone jack) for receiving a connector for transmitting/receiving audio signals to/from the external electronic device.

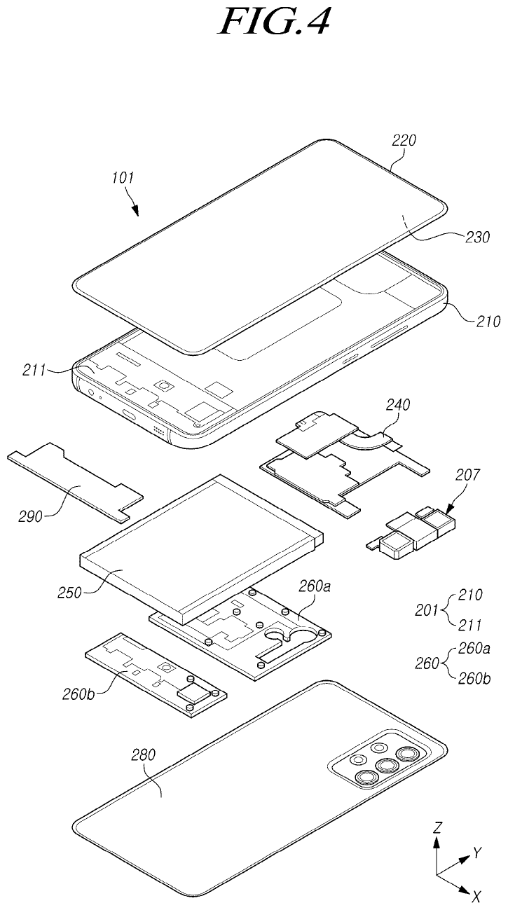

FIG. 4 is a front exploded perspective view illustrating an electronic device according to an embodiment of the disclosure.

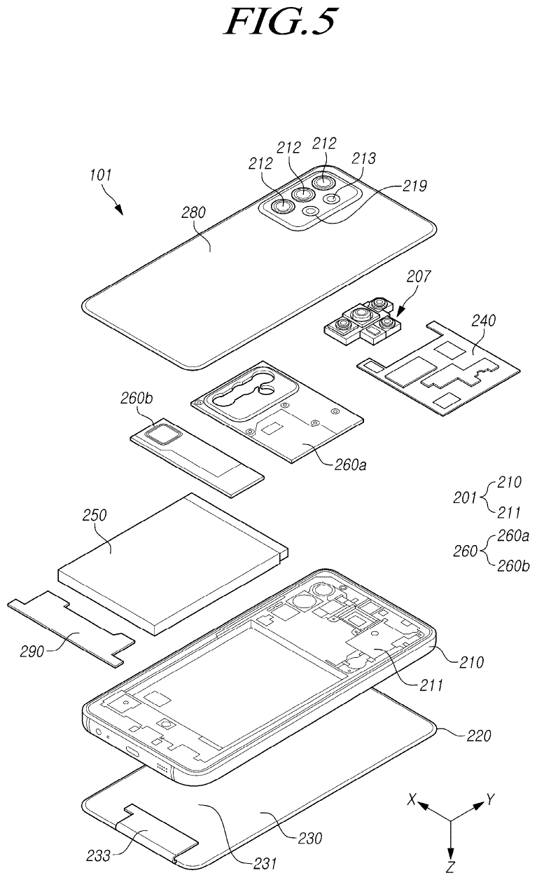

FIG. 5 is a rear exploded perspective view illustrating an electronic device according to an embodiment of the disclosure.

The components of the electronic device 101 of FIGS. 4 and 5 may be identical in whole or part to the components of the electronic device 101 of FIGS. 1 to 3.

Referring to FIGS. 4 and 5, an electronic device 101 (e.g., the electronic device 101 of FIG. 1, 2, or 3) may include a side structure 210, a first supporting member 211 (e.g., a bracket), a front plate 220 (e.g., the front plate 502 of FIG. 2), a display 230 (e.g., the display 115 of FIGS. 2 and 3), a printed circuit board (or a board assembly) 240, a battery 250, a second supporting member 260 (e.g., a rear case), an antenna, a camera assembly 207, and a rear plate 280 (e.g., the rear plate 111 of FIG. 3).

According to an embodiment, the electronic device 101 may exclude at least one (e.g., the first supporting member 211 or the second supporting member 260) of the components or may add other components. At least one of the components of the electronic device 101 may be the same or similar to at least one of the components of the electronic device 101 of FIG. 2 or 3 and no duplicate description is made below.

According to an embodiment, the first supporting member 211 may be disposed inside the electronic device 101 to be connected with the side structure 210 or integrated with the side structure 210. The first supporting member 211 may be formed of, e.g., a metallic material and/or non-metallic material (e.g., polymer). When at least partially formed of a metallic material, a portion of the side structure 210 or the first supporting member 211 may function as an antenna. The display 230 may be joined onto one surface of the first supporting member 211, and the printed circuit board 240 may be joined onto the opposite surface of the first supporting member 211. A processor (e.g., the processor 120 of FIG. 1), memory (e.g., the memory 130 of FIG. 1), and/or an interface (e.g., the interface 177 of FIG. 1) may be mounted on the printed circuit board 240. The processor may include one or more of, e.g., a central processing unit, an application processor, a graphic processing device, an image signal processing, a sensor hub processor, or a communication processor.

According to an embodiment, the first supporting member 211 and the side structure 210 may be collectively referred to as a front case or a housing 201. According to an embodiment, the housing 201 may be generally understood as a structure for receiving, protecting, or disposing the printed circuit board 240 or the battery 250. In an embodiment, the housing 201 may be understood as including a structure that the user may visually or tactfully recognize from the exterior of the electronic device 101, e.g., the side structure 210, the front plate 220, and/or the rear plate 280. In an embodiment, the ‘front or rear surface of the housing 201’ may mean the first surface 110A of FIG. 2 or the second surface 110B of FIG. 3. In an embodiment, the first supporting member 211 may be disposed between the front plate 220 (e.g., the first surface 110A of FIG. 2) and the rear plate 280 (e.g., the second surface 110B of FIG. 3) and may function as a structure for placing an electrical/electronic component, such as the printed circuit board 240 or the camera assembly 207.

According to an embodiment, the display 230 may include a display panel 231 and a flexible printed circuit board 233 extending from the display panel 231. It may be understood that the flexible printed circuit board 233 is, e.g., electrically connected to the display panel 231 while at least partially disposed on the rear surface of the display panel 231. In an embodiment, reference number ‘231’ may be understood as a protective sheet disposed on the rear surface of the display panel. For example, the protective sheet may be understood as a portion of the display panel 231 unless otherwise designated in the detailed description below. In an embodiment, the protective sheet may function as a cushioning structure that absorbs external force (e.g., a low-density elastic material, such as a sponge) or an electromagnetic shielding structure (e.g., a copper sheet (CU sheet)). According to an embodiment, the display 230 may be disposed on the inner surface of the front plate 220 and, by including a light emitting layer, output a screen through at least a portion of the front plate 220 or the first surface 110A of FIG. 2. As mentioned above, the display 230 may output substantially the entire area of the front plate 220 or the first surface 110A of FIG. 2.

According to an embodiment, the memory may include, e.g., a volatile or non-volatile memory.

According to an embodiment, the interface may include, e.g., a high definition multimedia interface (HDMI), a universal serial bus (USB) interface, a secure digital (SD) card interface, and/or an audio interface. The interface may electrically or physically connect, e.g., the electronic device 101 with an external electronic device and may include a USB connector, an SD card/multimedia card (MMC) connector, or an audio connector.

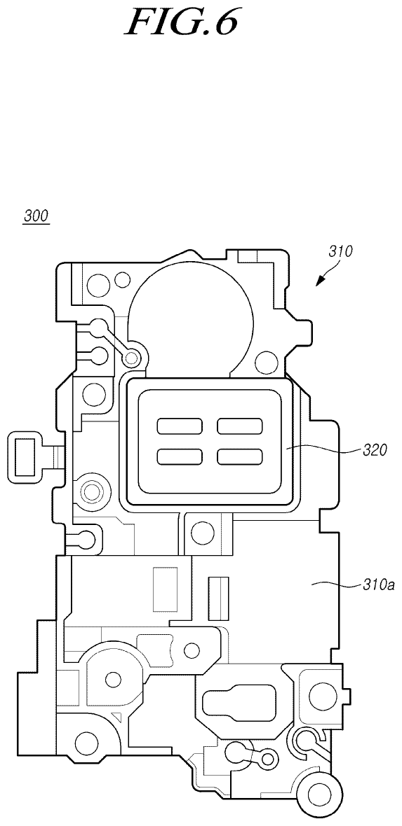

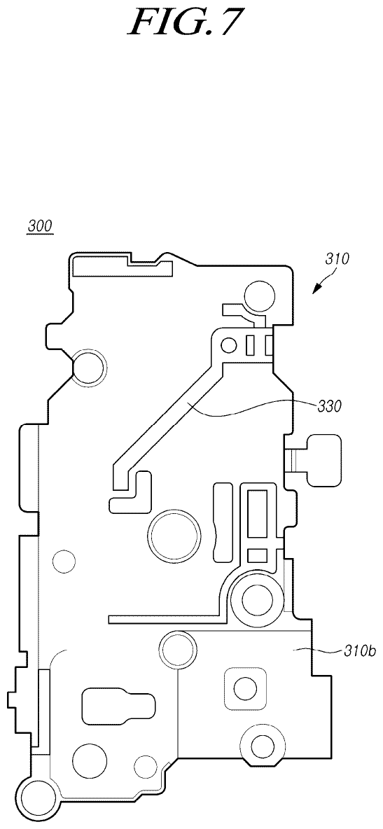

According to an embodiment, the second supporting member 260 may include, e.g., an upper supporting member 260a and a lower supporting member 260b. In an embodiment, the upper supporting member 260a, together with a portion of the first supporting member 211, may be disposed to surround the printed circuit board 240. A circuit device (e.g., a processor, a communication module, or memory) implemented in the form of an integrated circuit chip or various electrical/electronic components may be disposed on the printed circuit board 240. According to an embodiment, the printed circuit board 240 may receive an electromagnetic shielding environment from the upper supporting member 260a. In an embodiment, the lower supporting member 260b may be utilized as a structure in which electrical/electronic components, such as a speaker module (e.g., the speaker module 300 of FIGS. 6 and 7) and an interface (e.g., a USB connector, an SD card/MMC connector, or an audio connector) may be disposed. In an embodiment, electrical/electronic components, such as a speaker module and an interface (e.g., a USB connector, an SD card/MMC connector, or an audio connector) may be disposed on an additional printed circuit board (not shown). In this case, the lower supporting member 260b, together with the other part of the first supporting member 211, may be disposed to surround the additional printed circuit board. A speaker module or interface disposed on an additional printed circuit board (not shown) or lower supporting member 260b may be disposed corresponding to the connector hole (e.g., the first connector hole 508 or the second connector hole 109) or the audio module (e.g., the microphone hole 103 or the speaker hole (e.g., the external speaker hole 107 or the phone receiver hole 114)) of FIG. 2.

According to an embodiment, the battery 250 may be a device for supplying power to at least one component of the electronic device 101. The battery 189 may include, e.g., a primary cell which is not rechargeable, a secondary cell which is rechargeable, or a fuel cell. At least a portion of the battery 250 may be disposed on substantially the same plane as the printed circuit board 240. The battery 250 may be integrally or detachably disposed inside the electronic device 101.

According to an embodiment, the electronic device 101 may further include a separate sub circuit board 290 spaced apart from the printed circuit board 240 in the first supporting member 211. The sub circuit board 290 may be electrically connected with the printed circuit board 240 through a connecting member such as a connecting flexible board or a cable. The sub circuit board 290 may be electrically connected with electrical components disposed in an end area of the electronic device 101, such as the battery 289 or a speaker, a USB connector, an antenna connector, and/or a sim socket, and may transfer signals and power.

Although not shown, the antenna may include a conductor pattern implemented on the surface of the second supporting member 260 through, e.g., laser direct structuring. In an embodiment, the antenna may include a printed circuit pattern formed on the surface of the thin film. The thin film-type antenna may be disposed between the rear plate 280 and the battery 250. The antenna may include, e.g., a near-field communication (NFC) antenna, a wireless charging antenna, and/or a magnetic secure transmission (MST) antenna. The antenna may perform short-range communication with, e.g., an external device or may wirelessly transmit or receive power necessary for charging. In an embodiment of the disclosure, another antenna structure may be formed by a portion or combination of the side structure 210 and/or the first supporting member 211.

According to an embodiment, the camera assembly 207 may include at least one camera module. Inside the electronic device 101, the camera assembly 207 may receive at least a portion of the light incident through the optical hole or the camera windows 212, 213, and 219. In an embodiment, the camera assembly 207 may be disposed on the first supporting member 211 in a position adjacent to the printed circuit board 240. In an embodiment, the camera module(s) of the camera assembly 207 may be generally aligned with either one of the camera windows 212, 213, and 219 and be a least partially surrounded by the second supporting member 260 (e.g., the upper supporting member 260a).

FIG. 6 is a plan view illustrating a speaker module according to an embodiment of the disclosure.

FIG. 7 is a bottom view illustrating a speaker module according to an embodiment of the disclosure.

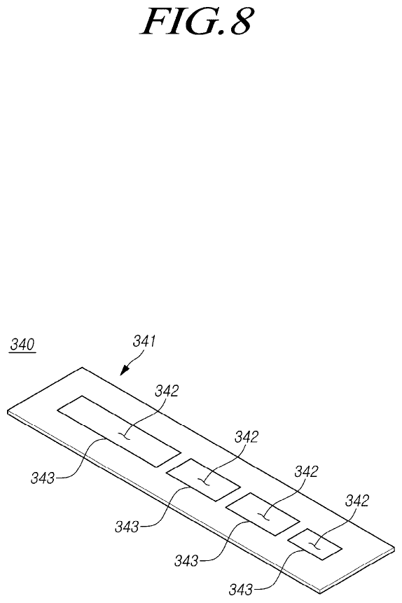

The embodiments of FIGS. 6 and 7 may be selectively combined with the embodiments of FIGS. 1 to 5 and the embodiments of FIGS. 8 to 10, 11A, 11B, and 12 to 22.

Referring to FIGS. 6 and 7, a speaker module 300 according to an embodiment may be disposed on a supporting member (e.g., the lower supporting member 260b of FIGS. 4 and 5) or a printed circuit board (e.g., the sub circuit board 290 of FIGS. 4 and 5) of an electronic device (e.g., the electronic device 101 of FIGS. 1 to 5). The speaker module 300 may be electrically connected to the printed circuit board.

According to an embodiment, the speaker module 300 may include a speaker housing 310, a speaker component 320 disposed on a first surface 310a of the speaker housing 310, and an antenna pattern portion 330 disposed on a second surface 310b opposite to the first surface 310a of the speaker housing 310. The speaker housing 310 may be referred to as an enclosure.

In an embodiment, the antenna pattern portion 330 may be formed of a conductor or a conductive pattern on a surface (e.g., the second surface 310b) of the speaker housing 310. The antenna pattern portion 330 may be a laser direct structuring (LDS) pattern. The antenna pattern portion 330 may be formed of, e.g., a conductive material including a metal material such as copper or nickel. The LDS pattern may be formed through a plating and coating process after selectively processing a pattern on an injection-molded product (e.g., a material including a thermoplastic resin) using a laser. Through laser processing, it is possible to facilitate the plating of a metal material on the rough resin surface in a micro scale. The antenna pattern portion 330 may be electrically connected to a communication module (e.g., the communication module 192 of FIG. 1) of the electronic device. The speaker module 300 may function as an antenna by including the antenna pattern portion 330 on a surface thereof. In this case, the speaker module 300 may be referred to as an antenna (or an antenna module and an antenna radiator).

According to an embodiment, the speaker module 300 may be an electronic component (hereinafter, referred to as a heat generation component) that generates heat when the speaker module 300 operates. In the case of a heat generation component such as the speaker module 300, a heat dissipation film (e.g., the heat dissipation film 340 of FIGS. 8 to 10) for dissipating heat generated during operation to the outside may be attached to the surface thereof.

The heat dissipation film may include, e.g., a graphite film or a copper film. The graphite film or copper film may be effective in heat dissipation by having high thermal conductivity. The graphite film or copper film may have high thermal conductivity as well as high electrical conductivity. However, when the graphite film or the copper film is attached to an electronic component (e.g., the speaker module 300) to which the antenna is coupled, it may affect the radiation characteristics of the antenna due to its high electrical conductivity, and thus may not be used for the antenna-coupled electronic component. Therefore, in the case of the antenna-coupled electronic component, a graphene fluoride (GF)-based heat dissipation film having high thermal conductivity and insulation properties may be attached. However, in the case of a graphene fluoride-based heat dissipation film, when manufacturing graphene fluoride particles, fluorine atoms having insulation properties are not uniformly bonded to the surface of graphene, and thus it is difficult to uniformly secure insulation properties. Further, in the case of a graphene fluoride-based heat dissipation film, it is difficult to form a film due to a low bonding force (or surface energy) between graphene fluoride particles when manufacturing the heat dissipation film. Further, in the case of a graphene fluoride-based heat dissipation film, a polymer-based binder formed of carbon, oxygen, and/or hydrogen may be used for forming a film, but in this case, the thermal conductivity of the film may be lowered.

Described below is a heat dissipation film having high thermal conductivity and insulation properties, which may address the foregoing issues.

FIG. 8 is a perspective view illustrating a heat dissipation film according to an embodiment of the disclosure.

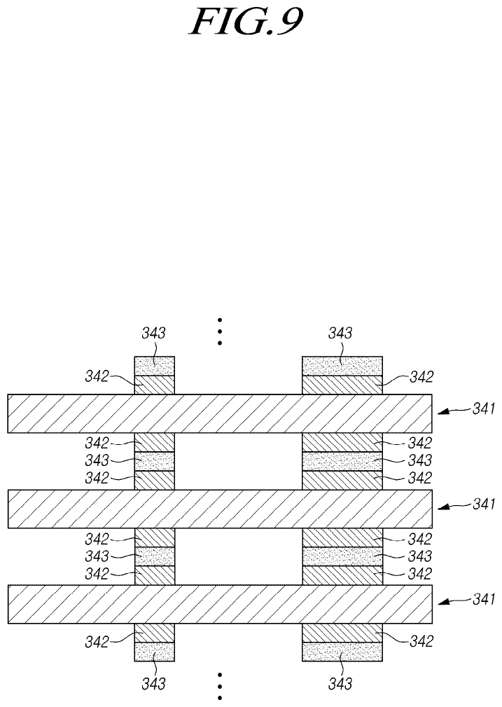

FIG. 9 is a cross-sectional view illustrating a heat dissipation film according to an embodiment of the disclosure.

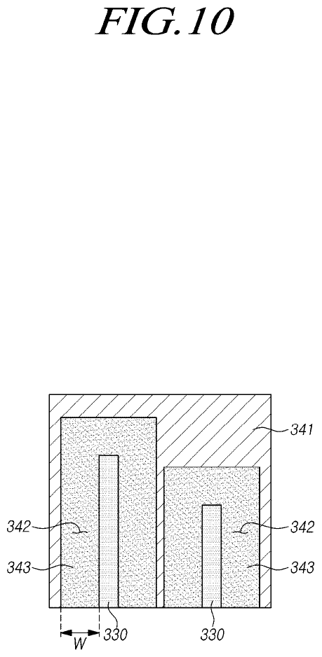

FIG. 10 is an enlarged view illustrating an area of an antenna pattern portion of a speaker module as illustrated in FIG. 7 according to an embodiment of the disclosure.

The embodiments of FIGS. 8 to 10 may be selectively combined with the embodiments of FIGS. 1 to 7, and FIGS. 11A, 11B, and 12 to 22.

Referring to FIGS. 8 and 9, a heat dissipation film 340 according to an embodiment may include a first layer 341 having high thermal conductivity, a second layer 342 stacked (or coated) on one surface of the first layer 341 and having adhesivity, and a third layer 343 stacked (or coated) on one surface of the second layer 342 and having an insulating property.

According to an embodiment, the first layer 341 may be configured based on graphene or graphite. The first layer 341 may include, e.g., graphene oxide (GO) in which oxygen (or a-0 functional group) is bonded to a carbon atom structure of graphene. The first layer 341 may be referred to as a base layer.

According to an embodiment, the second layer 342 may be stacked only in a specific area (e.g., an insulating area) on one surface of the first layer 341. The specific area may refer to an area in contact with the antenna pattern portion 330 of the speaker module within a predetermined width range. For example, the second layer 342 may be patterned only in the specific area to insulate from the antenna pattern portion 330. In an embodiment, the second layer 342 may be configured based on dopamine. The second layer 342 may be formed by polymerizing, e.g., dopamine molecules and may include poly dopamine (PDA) having a hydroxy group (or a —OH functional group) and/or a hydrogen atom on its surface. The second layer 342 may be a layer connecting the first layer 341 and the third layer 343. The second layer 342 may be referred to as an interface layer or an adhesive layer.

According to an embodiment, the third layer 343 may be stacked on one surface of the second layer 342 patterned on the first layer 341. For example, the third layer 343 may be disposed only in a specific area (e.g., an insulating area) on the one surface of the first layer 341, and may be patterned on the first layer 341 together with the second layer 342. In an embodiment, the third layer 343 may be formed of fluorocarbon-based polymer (FP) (or fluoropolymer). The third layer 343 may be referred to as an insulation layer.

According to an embodiment, the heat dissipation film 340 may be attached to a surface of a heat generation component (or an electronic component) (e.g., the speaker module 300) provided with an antenna (e.g., the antenna pattern portion 330).

Referring to FIG. 10, the second layer 342 and/or the third layer 343 may be provided to surround at least a portion of the antenna pattern portion 330 of the speaker module 300. The second layer 342 and/or the third layer 343 may space one area of the first layer 341 exposed on the surface of the heat dissipation film 340 apart from the antenna pattern portion 330 within a predetermined distance range so that the exposed one area of the first layer 341 does not affect antenna radiation performance. For example, the second layer 342 and/or the third layer 343 may be stacked on the first layer 341 to have substantially the same width w as the separation distance between one area of the first layer 341 and the antenna pattern portion 330. The width w of the second layer 342 and/or the third layer 343 may be designed to be within a range that does not affect the radiation performance of the antenna, e.g., within 2 mm.

According to an embodiment, the first layer 341, the second layer 342, and the third layer 343 may form a plurality of basic unit structures constituting the heat dissipation film 340. For example, the plurality of basic unit structures including the layers 341, 342, and 343 may be repeatedly stacked by the second layer 342, which functions as an adhesive layer, in an order such as “first layer 341—second layer 342—third layer 343—second layer 342—first layer 341 . . . ”. In other words, the second layer 342 may be disposed between the plurality of basic unit structures. The thickness of the basic unit structure may be designed to be, e.g., within 0.1 to 1 um. The heat dissipation film 340 may have a predetermined thickness required by continuously stacking the basic unit structures. The thickness of the heat dissipation film 340 may be designed to be, e.g., within 10 um.

The heat dissipation film 340 may have a high thermal conductivity of 1000 W/mK or more by being manufactured to a predetermined thickness through stacking of the basic unit structures. And the heat dissipation film 340 may also have insulation properties through the patterned second and third layers 342 and 343.

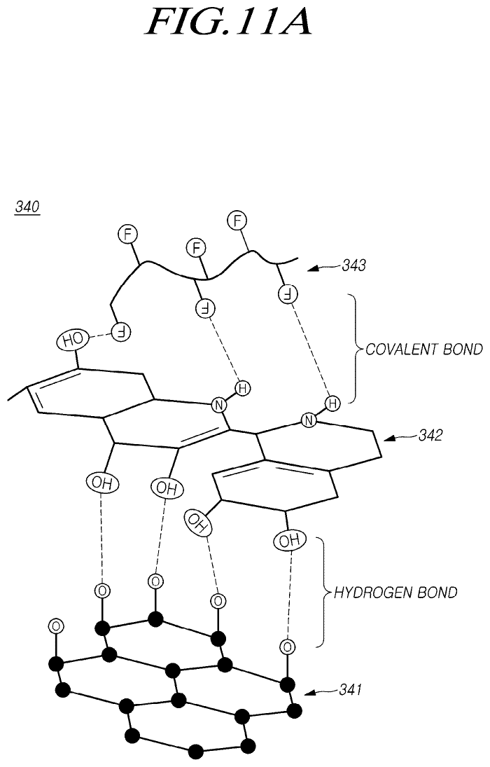

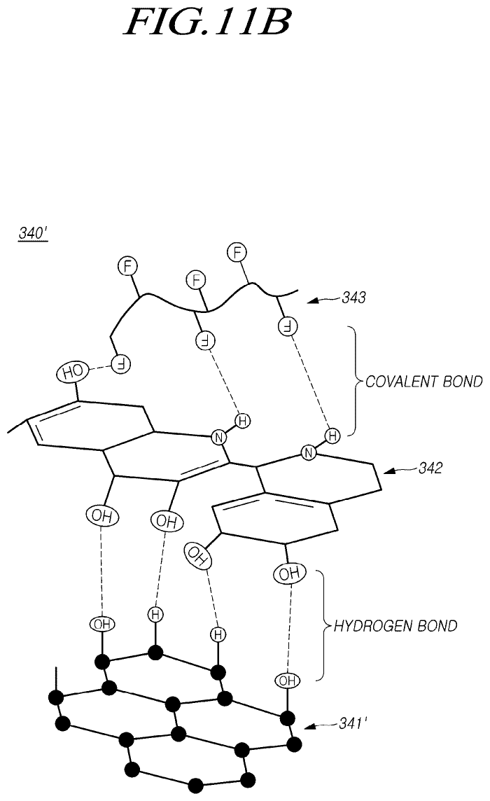

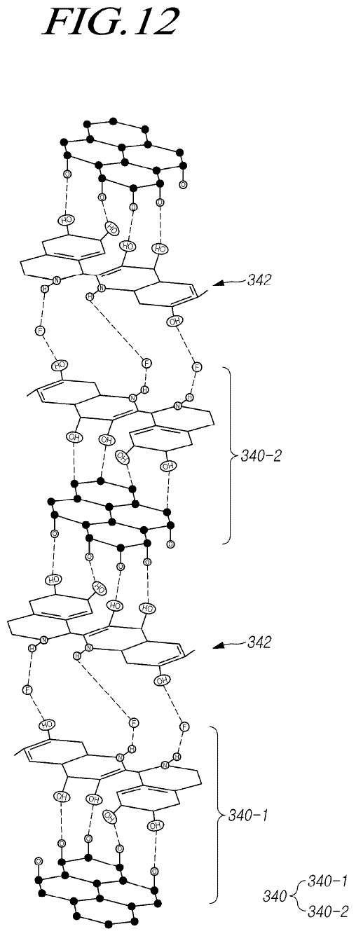

Hereinafter, a coupled structure and a stacked structure between layers 341, 342, and 343 constituting the heat dissipation film 340 are described with reference to FIGS. 11A, 11B, and 12.

FIG. 11A is a view illustrating a coupled structure of layers constituting a heat dissipation film according to an embodiment of the disclosure.

FIG. 11B is a view illustrating a coupled structure of layers constituting a heat dissipation film according to an embodiment of the disclosure.

FIG. 12 is a view illustrating a stacked structure of a heat dissipation film according to an embodiment of the disclosure.

According to an embodiment, the heat dissipation film 340 or 340′ may include a first layer 341 or 341′, a second layer 342, and a third layer 343.

The configuration of the heat dissipation film 340 or 340′ of FIGS. 11A, 11B, and 12 may be identical in whole or part to the configuration of the heat dissipation film 340 of FIGS. 8 to 10.

The embodiments of FIGS. 11A, 11B, and 12 may be selectively combined with the embodiments of FIGS. 1 to 10, and FIGS. 13 to 22.

Referring to FIG. 11A, the second layer 342 according to an embodiment may be chemically coupled to one side of the graphene-based first layer 341. For example, when the first layer 341 is formed of graphene oxide (GO) and the second layer 342 is formed of polydopamine (PDA), the first layer 341 and the second layer 342 may be coupled to each other by hydrogen bonding of the oxygen atom present on the surface of the first layer 341 and the hydroxyl group present on the surface of the second layer 342. According to an embodiment, the third layer 343 may be chemically coupled to one side of the second layer 342. For example, when the second layer 342 is formed of polydopamine (PDA) and the third layer 343 is formed of a fluorine-based polymer (FP), the hydroxy group and/or the hydrogen atom present on the surface of the second layer 342 and the fluorine (F) atom present on the surface of the third layer 343 may be covalently bonded to each other. Accordingly, the first layer 341, the second layer 342, and the third layer 343 may be sequentially stacked to form one basic unit structure.

Referring to FIG. 11B, the first layer 341′ according to an embodiment may be formed of graphite (GR), unlike the first layer 341 formed of graphene oxide illustrated in FIG. 11A. In this case, on the surface of the first layer 341′ of FIG. 11B, a hydrogen atom and/or a hydroxyl group may be present instead of the oxygen atom present on the surface of the first layer 341 of FIG. 11A. In an embodiment, the second layer 342 may be chemically coupled to one side of the first layer 341′ formed of graphite GR. For example, when the first layer 341′ is formed of graphite (GR) and the second layer 342 is formed of polydopamine (PDA), the first layer 341′ and the second layer 342 may be coupled to each other by hydrogen bonding of the hydrogen atom and/or the hydroxy group present on the surface of the first layer 341′ and the hydroxy group present on the surface of the second layer 342. As described above, the third layer 343 may be covalently bonded with the second layer 342. Accordingly, the first layer 341′, the second layer 342, and the third layer 343 may be sequentially stacked to form one basic unit structure.

Referring to FIG. 12, as illustrated in FIG. 11A, as the plurality of basic unit structures 340-1 and 340-2 including the first layer 341, the second layer 342, and the third layer 343 are repeatedly stacked through the second layer 342 which is an adhesive layer, the heat dissipation film 340 having a predetermined thickness may be formed. For example, the plurality of basic unit structures 340-1, 340-2, . . . may be stacked so that the thickness of the heat dissipation film 340 meets within 10 μm.

Although not illustrated, even in the case of the basic unit structure in which the first layer 341′ illustrated in FIG. 11B is formed of graphite, a plurality of basic unit structures including the first layer 341′, the second layer 342, and the third layer 343 may be repeatedly stacked through the second layer 342 which is an adhesive layer, thereby forming a heat dissipation film 340′ having a predetermined thickness.

TABLE 1

| | 1 | 2 | 3 | 4 | 5 | 6 | 7 | 8 | 9 | 10 | average |
|---|---|---|---|---|---|---|---|---|---|---|---|
| A | 2.11 | 2.03 | 2.24 | 2.09 | 2.13 | 2.17 | 2.05 | 2.08 | 2.16 | 2.12 | 2.12 |
| B | 2.88 | 2.92 | 2.84 | 2.85 | 2.95 | 2.9 | 2.89 | 2.84 | 2.86 | 2.87 | 2.88 |

Table 1 shows the permittivity of each sample of the heat dissipation film B having a thickness of about 10 um by stacking a plurality of basic unit structures and one basic unit structure A. Referring to Table 1, it may be identified that one basic unit structure A has an average permittivity of 2.12 F/m, and the heat dissipation film B having a thickness of about 10 um has an average permittivity of 2.88 F/m, and accordingly, it may be identified that insulation properties are maintained before/after stacking of the basic unit structures.

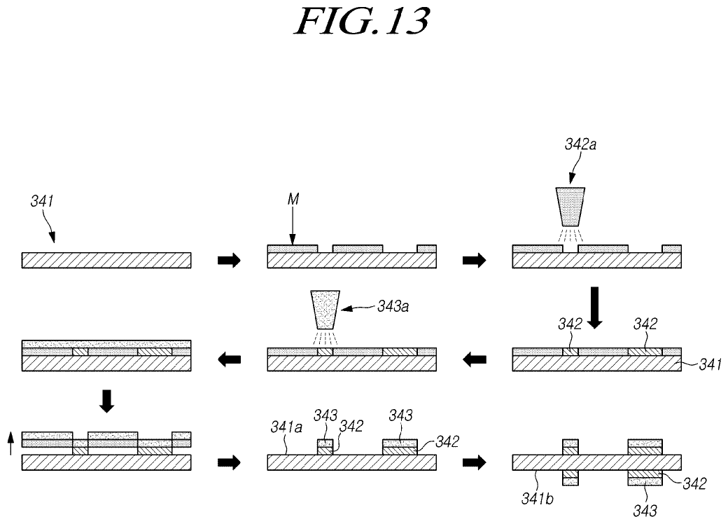

FIG. 13 is a flowchart illustrating manufacturing a basic unit structure constituting a heat dissipation film according to an embodiment of the disclosure.

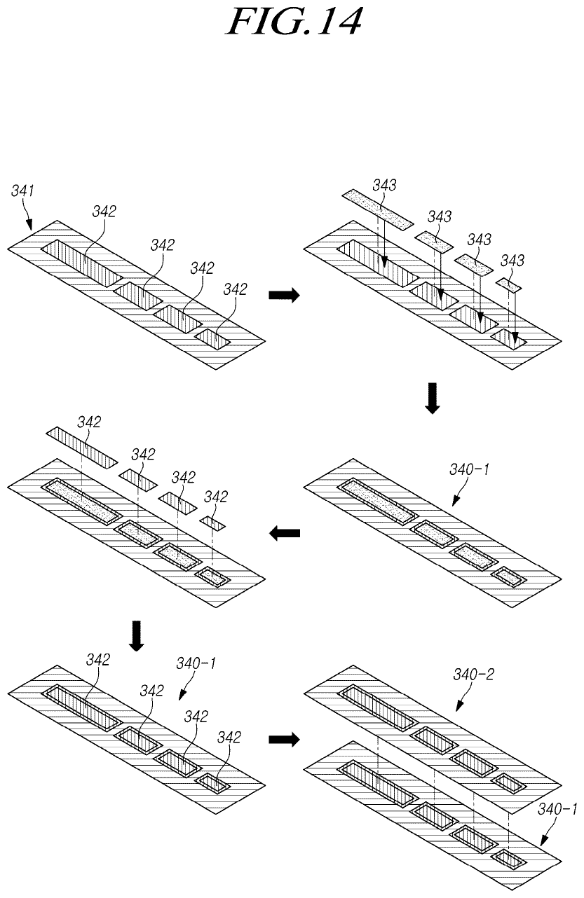

FIG. 14 is a flowchart illustrating manufacturing a heat dissipation film according to an embodiment of the disclosure.

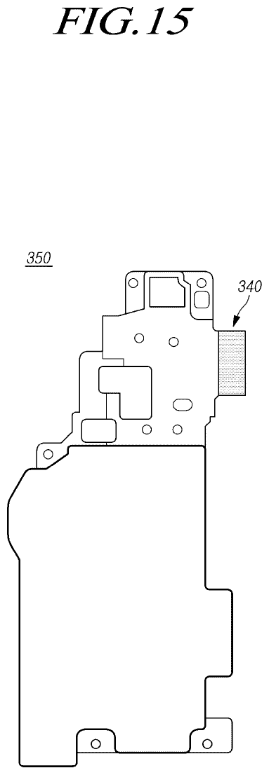

The embodiments of FIGS. 13 and 14 may be selectively combined with the embodiments of FIGS. 1 to 10, 11A, 11B, and 12 and the embodiments of FIGS. 15 to 22.

According to an embodiment, the process of patterning the second layer 342 and/or the third layer 343 on the first layer 341 may be performed by at least one of spray coating, deep coating, and/or screen printing based on the masking process.

Referring to FIG. 13, the mask M is attached to one area of the surface area of the first layer 341 (e.g., the graphene oxide GO) that does not require insulation. Further, the raw material 342a (e.g., polydopamine (PDA)) of the second layer 342 is sprayed (or applied) to one side of the first layer 341 to which the mask M is attached, so that the second layer 342 (e.g., polydopamine (PDA)) is stacked in an area (or insulating area) in which the mask M is not disposed. Thereafter, the mask M, the second layer 342 and the raw material 343a of the third layer 343 are stacked on the upper surface of the first layer 341 by spraying (or applying) the raw material 343a (e.g., the fluorine-based polymer FP) of the third layer 343 on one side of the first layer 341. Thereafter, when the mask M attached to the surface of the first layer 341 is removed, the second layer 342 and the third layer 343 may be patterned only in the insulating area which requires insulation. By repeating the above process, the second layer 342 and the third layer 343 may be patterned on the other side 341b of the first layer 341 opposite to the one side 341a of the first layer 341 only in the insulating area.

Referring to FIG. 14, a basic unit structure 340-1 constituting the heat dissipation film 340 may be formed by sequentially stacking the second layer 342 and the third layer 343 on the area requiring insulation on the surface of the first layer 341 in the same manner as illustrated in FIG. 13. Thereafter, the second layer 342 may be stacked again on the third layer 343 of the basic unit structure 340-1, and then another basic unit structure 340-2 may be stacked on the basic unit structure 340-1, thereby continuously stacking the basic unit structures 340-1 and 340-2. In other words, the basic unit structures 340-1 and 340-2 may be stacked in the above-described manner to form a heat dissipation film 340 having a desired thickness.

FIG. 15 is a plan view illustrating an antenna according to an embodiment of the disclosure.

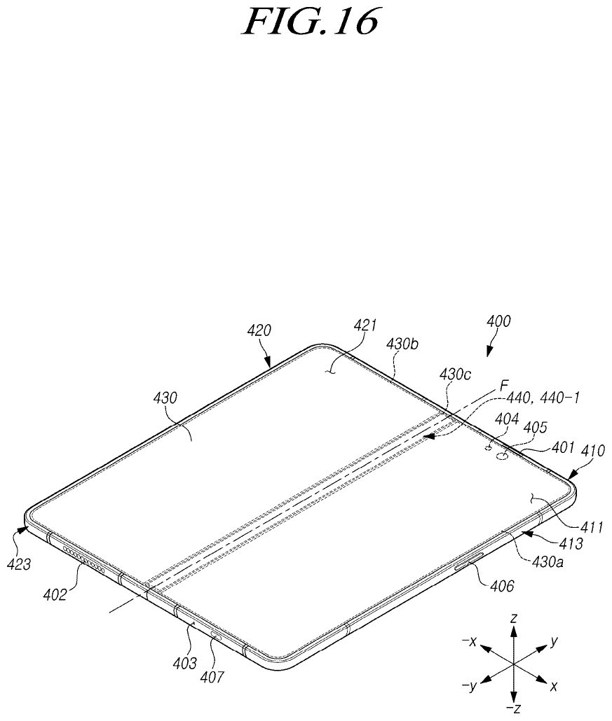

The embodiment of FIG. 15 may be selectively combined with the embodiments of FIGS. 1 to 10, 11A, 11B, and 12 to 14 or the embodiments of FIGS. 16 to 22.

Referring to FIG. 15, an electronic device (e.g., the electronic device 101 of FIGS. 4 and 5) according to an embodiment may include one or more antenna 350 (e.g., an NFC antenna, a wireless charging antenna, or an MST antenna) disposed between a rear plate (e.g., the rear plate 280 of FIGS. 3 and 4) of the electronic device and a battery (e.g., the battery 250 of FIGS. 3 and 4).

According to an embodiment, the antenna 350 may be provided in the form of a thin film. Although not shown, the antenna 350 may include a printed circuit pattern, a wireless charging circuit, or a heat dissipation sheet formed on the surface of the thin film.

According to an embodiment, the antenna 350 (e.g., MST antenna) (e.g., first antenna) may include a heat dissipation film 340 disposed to overlap another antenna (e.g., an mmWave antenna module) (e.g., second antenna) provided in the electronic device. The heat dissipation film 340 may be integrally provided with the thin film of the antenna. The heat dissipation film 340 has high thermal conductivity and insulation properties as described above, and is integrally provided with the antenna 350, thereby additionally securing a heat transfer path and hence enhancing heat dissipation of another antenna provided in the electronic device.

In the disclosure, a speaker module (e.g., the speaker module 300 of FIGS. 6 and 8) and an antenna 350 have been described as electronic components (or heat generation components) to which the antenna to which the heat dissipation film 340 is attached is coupled, but the disclosure is not limited thereto, and the heat dissipation film 340 may be applied to any components that are related to radiation properties of the antenna as heat generation components.

FIG. 16 is a front perspective view illustrating an electronic device according to an embodiment of the disclosure.

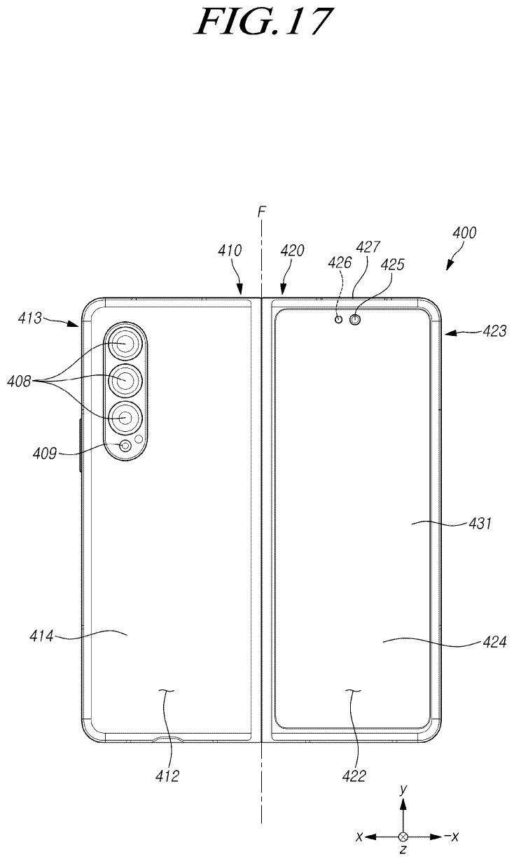

FIG. 17 is a rear plan view illustrating an electronic device according to an embodiment of the disclosure.

Referring to FIGS. 16 and 17, the electronic device 400 may be coupled to be foldable with respect to each other through at least one hinge device 440 or 440-1 (e.g., a hinge module or a hinge structure) with respect to the folding axis F, and may include a first housing 410 (e.g., a first housing structure) including a first side member 413 (e.g., a side bezel) and a second housing 420 (e.g., a second housing structure) including a second side member 423 (e.g., a side bezel). For example, the first housing 410 and the second housing 420 may be configured as a foldable housing (e.g., a housing structure). For example, the electronic device 400 may include a first display 430 (e.g., a flexible display, a foldable display, or a main display) disposed to be supported by the first housing 410 and the second housing 420. For example, the first housing 410 may include a first surface 411 and a second surface 412 facing away from the first surface 411 (e.g., the −z-axis direction). For example, the second housing 420 may include a third surface 421 and a fourth surface 422 facing away from the third surface 421 (e.g., the −z-axis direction). For example, the first housing 410 may include a first rear cover 414 coupled to the first side member 413. For example, the second housing 420 may include a second rear cover 424 coupled to the second side member 423. For example, when the electronic device 400 is in the fully unfolded first state (e.g., an unfolded state or opened state), the electronic device 400 may be operated so that the first surface 411 and the third surface 421 face in substantially the same direction (e.g., the z-axis direction). For example, when the electronic device 400 is in a fully folded second state (e.g., a folded state or closed state), the electronic device 400 may be operated so that the first surface 411 and the third surface 421 face each other or face away from each other. For example, the electronic device 400 may be operated to maintain a third state (e.g., an intermediate state) between the first state and the second state.

According to an embodiment, the electronic device 400 may include a first receiver 401 disposed on the first surface 411 of the first housing 410, at least one first sensor module 404 (e.g., an illuminance sensor), and/or at least one first camera module 405 (e.g., an under display camera (UDC)). For example, the electronic device 400 may include at least one key 406 disposed on the first side member 413. For example, the electronic device 400 may include at least one second camera module 408 and/or a flash 409 disposed on the second surface 412 (e.g., the first rear cover 414) of the first housing 410. For example, the electronic device 400 may include a second display 431, at least one third camera module 425 (e.g., under display camera (UDC)), at least one second sensor module 426, and/or a second receiver 427 disposed on the fourth surface 422 of the second housing 420. For example, the second display 431 may be disposed to be visible from the outside through at least a portion of the second rear cover 424. For example, the electronic device 400 may include a speaker 402 disposed on the second side member 423, a microphone 403 disposed on the first side member 413, and/or a connector port 407. At least some of the above-described plurality of components may be disposed in the first housing 410 and/or the second housing 420.

According to an embodiment, the first display 430 (e.g., a flexible display) may include a first area 430a (e.g., a first flat portion) corresponding to at least a portion of the first surface 411, a second area 430b (e.g., a second flat portion) corresponding to at least a portion of the third surface 421, and a third area 430c (e.g., a flexible portion) that connects the first area 430a and the second area 430b and in which the electronic device 400 deforms from the second state (e.g., the folded state) and/or the third state. For example, the third area 430c may be disposed at a position at least partially overlapping the at least one hinge device 440 or 440-1 when the first display 430 is viewed from above (e.g., in the z-axis direction). For example, in the second state, the first display 430 may be disposed not to be visible from the outside (e.g., inward-fold type) as the first surface 411 and the third surface 421 face each other. For example, in the second state, the first display 430 may be disposed to be visible from the outside as the first surface 411 and the third surface 421 face away from each other (e.g., an outward-fold type).

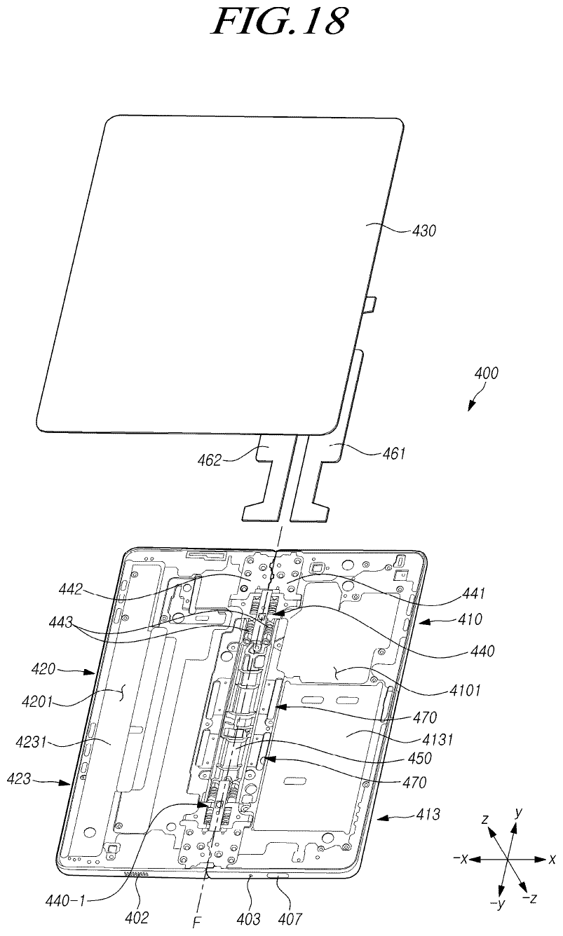

FIG. 18 is a partially exploded perspective view illustrating the electronic device of FIGS. 16 and 17 including a hinge device according to various embodiments of the disclosure.

The embodiment of FIG. 18 may be selectively combined with the embodiments of FIGS. 16, 17, and 19 to 22.

Referring to FIG. 18, the electronic device 400 may include at least one hinge device 440 or 440-1 (e.g., a hinge module or a hinge structure) connecting the first housing 410 and the second housing 420 under the first display 430 (e.g., in the −z-axis direction). For example, the at least one hinge device 440 or 440-1 may include a first hinge device 440 and a second hinge device 440-1 spaced apart from the first hinge device 440 along a direction (e.g., +y-axis direction) parallel to the folding axis F. For example, the at least one hinge device 440 or 440-1 may be supported by the first supporting member 4131 extending from the first side member 413 to the first space 4101 of the first housing 410 and the second supporting member 4231 extending from the second side member 423 to the second space 4201 of the second housing 420. For example, the at least one hinge device 440 or 440-1 may be disposed between the first housing 410 and the second housing 420 so as not to be visible from the outside through the hinge housing 450 (e.g., a hinge cover).

According to an embodiment, the first hinge device 440 may include a first rotation member 441 (e.g., a first arm or a first rotator) disposed on the first supporting member 4131 of the first housing 410, a second rotation member 442 (e.g., a second arm or a second rotator) disposed on the second supporting member 4231 of the second housing 420, and a gear assembly 443 connected to the first housing 410 and the second housing 420 to allow the first housing 410 and the second housing 420 to symmetrically rotate about each other. For example, the gear assembly 443 may include a plurality of gears (e.g., spur gears and/or worm gears) engaged with respect to each other. For example, the gear assembly 443 may include a cam coupled structure to press the first housing 410 and the second housing 420 in a direction of switching from a first state (e.g., an unfolded state or opened state) to a second state (e.g., a folded state or closed state) or from the second state to the first state based on a predetermined angle with respect to each other, and to provide a pre-stop at various folding angles. For example, the second hinge device 440-1 may have substantially the same configuration as the first hinge device 440.

According to an embodiment, the electronic device 400 may include a first hinge plate 461 connected to the first supporting member 4131 and/or the first rotation member 441. The electronic device 400 may include a second hinge plate 462 connected to the second supporting member 4231 and/or the second rotation member 442. For example, the at least one hinge device 440 or 440-1, the first rotation member 441, the second rotation member 442, the first hinge plate 461, and the second hinge plate 462 may form substantially the same plane as the first supporting member 4131 and the second supporting member 4231 when the electronic device 400 is in the first state. For example, the second hinge device 440-1 may be substantially symmetrical to the first hinge device 440 or may have substantially the same configuration as the first hinge device 440.

According to an embodiment, although not illustrated, the electronic device 400 may include a plurality of printed circuit boards separately disposed in the housings 410 and 420. A processor (e.g., the processor 120 of FIG. 1), memory (e.g., the memory 130 of FIG. 1), and/or an interface (e.g., the interface 177 of FIG. 1) may be mounted on the plurality of printed circuit boards.

According to an embodiment, the electronic device 400 may include a plurality of connectors 470 for electrical connection (e.g., transmission of a control signal, power, or communication signal) between various components or electrical connection between printed circuit boards. Various types of connection structures (or connector structures) may be employed in the plurality of connectors 470, such as a flexible printed circuit (FPC) or flexible flat cable (FFC) type, a board to board type (B to B), a zip type, a bonding type formed through a hot bar process, a low insertion force (LIF), and a zero insertion force (ZIF), through which related components may be electrically coupled or each printed circuit board may be electrically coupled. In addition to the various types of connection structures, the plurality of connectors 470 may employ a connector-to-connector type (or C2C type) electrical connection structure (or connector structure) connecting two different connectors 470.

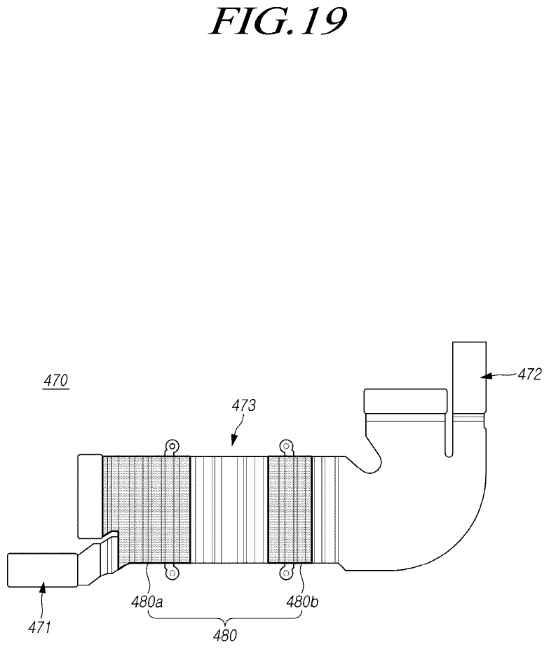

FIG. 19 is a plan view illustrating a connector according to an embodiment of the disclosure.

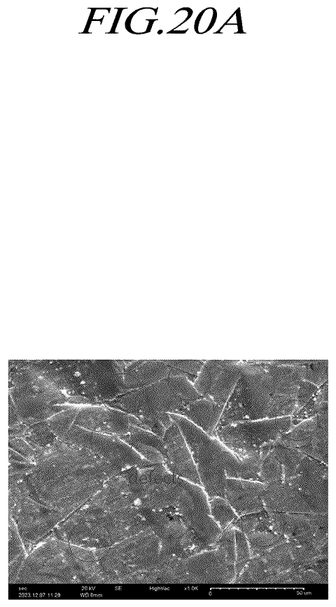

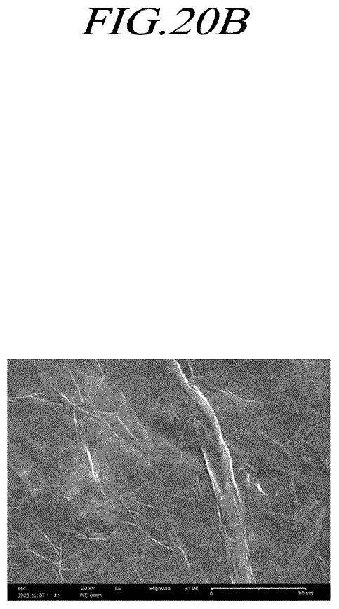

FIGS. 20A and 20B are views illustrating a bonding force between particles constituting a heat dissipation film according to embodiments of the disclosure.

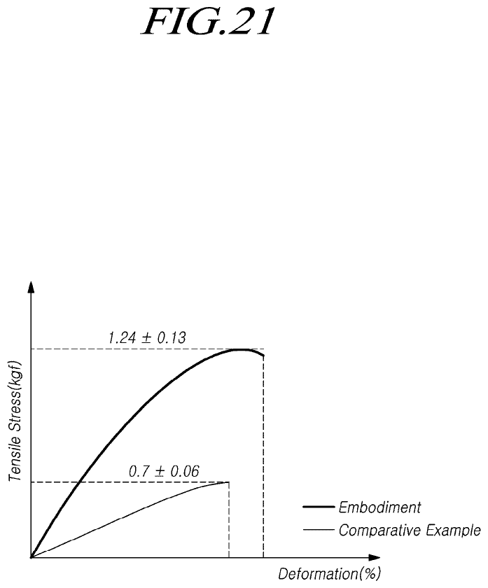

FIG. 21 is a graph illustrating a tensile stress of a heat dissipation film according to an embodiment of the disclosure.

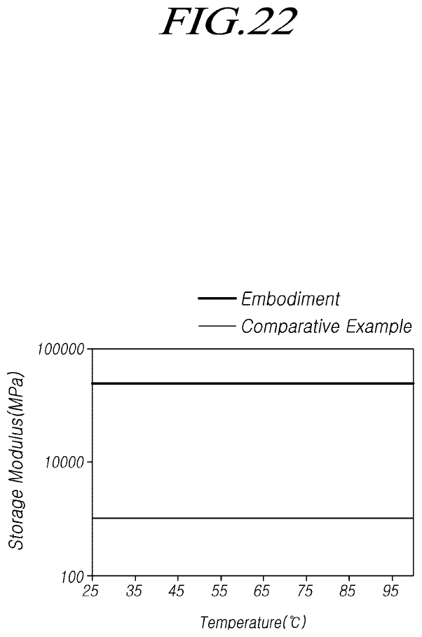

FIG. 22 is a graph illustrating a storage modulus of a heat dissipation film according to an embodiment of the disclosure.

The embodiments of FIGS. 19 to 22 may be selectively combined with the embodiments of FIGS. 1 and 16 to 18.

The configuration of the heat dissipation film 480 of FIG. 19 may be identical in whole or part to the configuration of the heat dissipation film 340 of FIGS. 8 to 10, 11A, 11B, and 12 to 14.

Referring to FIG. 19, the connector 470 according to an embodiment may include a first connection portion 471 electrically connected to various components or a printed circuit board at one end portion thereof, a second connection portion 472 electrically connected to various components or a printed circuit board at the other end portion thereof, and a flexible portion 473 that connects the first connection portion 471 and the second connection portion 472 and is bendable. The flexible portion 473 of the connector 470 may be a portion overlapping a third area (e.g., the third area 430c of FIG. 16) of a first display (e.g., the first display 430 of FIG. 16) of an electronic device (e.g., the electronic device 400 of FIG. 16). The flexible portion 473 of the connector 470 may be deformed together with the first display when the housings (e.g., the first housing 410 and the second housing 420 of FIG. 16) of the electronic device rotate.

According to an embodiment, the heat dissipation film 480 may be attached to the flexible portion 473 of the connector 470. The heat dissipation films 480a or 480b may be separately attached to the flexible portion 473 of the connector 470. The heat dissipation film 480 attached to the flexible portion 473 of the connector 470 may be used as a heat transfer path of various electronic components and/or printed circuit boards connected to each other through the connector 470. The heat dissipation film 480 may be a graphite-based film. However, in the case of the graphite-based heat dissipation film 480, when the flexible portion 473 of the connector 470 is deformed, the heat dissipation film 480 may be peeled off from the connector 470 due to a low bonding force between graphite particles, and a signal loss may occur due to high electrical conductivity. Accordingly, as described above with reference to FIGS. 8 to 10, 11A, 11B, 12, and 13, the heat dissipation film 480 may include a first layer (e.g., the first layer 341 of FIG. 8) formed based on graphene, a second layer (e.g., the second layer 342 of FIG. 8) formed based on polydopamine, and a third layer (e.g., the third layer 343 of FIG. 8) formed of a fluorine-based polymer. In the heat dissipation film 480, the third layer formed of a fluorine-based polymer may be omitted as necessary.

When the heat dissipation film 480 is formed based on graphene and polydopamine, polydopamine may function as an adhesive when the graphene particles are bonded, and may compensate for defects that may occur when the graphene particles are bonded. As a result, the bonding force between the graphene particles may increase, and the bendability of the heat dissipation film 480 may be enhanced (see FIG. 20A and FIG. 20B). Further, when the heat dissipation film 480 is formed based on graphene and polydopamine (embodiment), the tensile stress of the heat dissipation film may be enhanced from 0.7 kgf to 1.24 kgf (see FIG. 21), and the storage modulus may also be enhanced from 4885 MPA (@25° C.) to 14069 (@25° C.) (see FIG. 22), compared to when the heat dissipation film 480 is formed based on graphite (comparative example).

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The storage medium readable by the machine may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

An electronic device 101 according to an embodiment of the disclosure may comprise a housing 110, a circuit board 240 disposed in the housing 110, an antenna module 300 disposed in the housing 110 and including an antenna pattern portion 330 electrically connected to the circuit board, and a heat dissipation film 340 attached to the antenna module 300. The heat dissipation film 340 may include a first layer 341 formed of a conductive material, a second layer 342 having a predetermined width to surround the antenna pattern portion 330 and disposed on one surface of the first layer 341, and a third layer 343 disposed on one surface of the second layer 342 and formed of an insulating material. The second layer 342 may be configured to be hydrogen-bonded with the first layer 341 and covalently bonded with the third layer 343.

According to an embodiment, the heat dissipation film 340 may include a plurality of basic unit structures in which the first layer 341, the second layer 342, and the third layer 343 are sequentially stacked. The heat dissipation film 340 may be configured so that the plurality of basic unit structures are repeatedly stacked, and the second layer 342 may be disposed between the plurality of basic unit structures.

According to an embodiment, the first layer 341 may include a graphene- or graphite-based unit.

According to an embodiment, the second layer 342 may include a dopamine-based unit.

According to an embodiment, the third layer 343 may include a fluoride-based unit.

According to an embodiment, the third layer 343 may be formed of a fluorocarbon-based polymer (FP).

According to an embodiment, the second layer 342 may have substantially the same width as a predetermined width of the third layer 343.

According to an embodiment, the predetermined width of the second layer 342 may be 2 mm or less.

According to an embodiment, the electronic device 101 may further include a first antenna 350 and a second antenna. The first antenna 350 may include a heat dissipation film 340 disposed to overlap the second antenna.

According to an embodiment, the antenna module 300 may include a speaker module or a camera module having an antenna pattern portion electrically connected to the circuit board.

A heat dissipation film 340 attached to an antenna module 300 having an antenna pattern portion 330, according to an embodiment of the disclosure, may comprise a first layer 341 formed of a conductive material, a second layer 342 having a predetermined width to surround the antenna pattern portion 330 and disposed on one surface of the first layer 341, and a third layer 343 disposed on one surface of the second layer 342 and formed of an insulating material. The second layer 342 may be hydrogen-bonded with the first layer 341 and covalently bonded with the third layer 343.

According to an embodiment, the first layer 341 may include a graphene- or graphite-based unit.

According to an embodiment, the second layer 342 may include a dopamine-based unit.

According to an embodiment, the third layer 343 may include a fluoride-based unit.

According to an embodiment, the second layer 342 may have substantially the same width as a predetermined width of the third layer 343.

According to an embodiment, the predetermined width of the second layer 342 may be 2 mm or less.

According to an embodiment, the antenna pattern portion 330 may comprise a thin film antenna.

According to an embodiment, the antenna pattern portion 330 may comprise at least one of a near field communication (NFC) antenna, a wireless charging antenna, or a magnetic secure transmission (MST) antenna.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device, comprising:
a housing;
a circuit board disposed in the housing;
an antenna module disposed in the housing and including an antenna pattern portion electrically connected to the circuit board; and
a heat dissipation film attached to the antenna module,
wherein the heat dissipation film includes:
a first layer formed of a conductive material,
a second layer having a predetermined width to surround the antenna pattern portion and disposed on one surface of the first layer, and
a third layer disposed on one surface of the second layer and formed of an insulating material, and
wherein the second layer is configured to be hydrogen-bonded with the first layer and covalently bonded with the third layer.

2. The electronic device of claim 1,
wherein the heat dissipation film includes a plurality of basic unit structures in which the first layer, the second layer, and the third layer are sequentially stacked, wherein the heat dissipation film is configured so that the plurality of basic unit structures are repeatedly stacked, and
wherein the second layer is disposed between the plurality of basic unit structures.

3. The electronic device of claim 1, wherein the first layer includes a graphene- or graphite-based unit.

4. The electronic device of claim 1, wherein the second layer includes a dopamine-based unit.

5. The electronic device of claim 1, wherein the third layer includes a fluoride-based unit.

6. The electronic device of claim 5, wherein the third layer is formed of a fluorocarbon-based polymer (FP).

7. The electronic device of claim 1, wherein the second layer has substantially the same width as a predetermined width of the third layer.

8. The electronic device of claim 1, wherein the predetermined width of the second layer is 2 mm or less.

9. The electronic device of claim 1, wherein the antenna module includes a speaker module or a camera module having an antenna pattern portion electrically connected to the circuit board.

10. The electronic device of claim 1,
further comprising a first antenna and a second antenna,
wherein the first antenna includes a heat dissipation film disposed to overlap the second antenna.

11. A heat dissipation film attached to an antenna module having an antenna pattern portion,
wherein the heat dissipation film includes:
a first layer formed of a conductive material,
a second layer having a predetermined width to surround the antenna pattern portion and disposed on one surface of the first layer, and
a third layer disposed on one surface of the second layer and formed of an insulating material, and
wherein the second layer is hydrogen-bonded with the first layer and covalently bonded with the third layer.

12. The heat dissipation film of claim 11,
wherein the heat dissipation film includes a plurality of basic unit structures including the first layer, the second layer, and the third layer,
wherein the heat dissipation film is configured so that the plurality of basic unit structures are repeatedly stacked, and
wherein the second layer is disposed between the plurality of basic unit structures.

13. The heat dissipation film of claim 11, wherein the first layer includes a graphene- or graphite-based unit.

14. The heat dissipation film of claim 11, wherein the second layer includes a dopamine-based unit.

15. The heat dissipation film of claim 11, wherein the third layer includes a fluoride-based unit.

16. The heat dissipation film of claim 15, wherein the third layer is formed of a fluorocarbon-based polymer (FP).

17. The heat dissipation film of claim 11, wherein the second layer has substantially the same width as a predetermined width of the third layer.

18. The heat dissipation film of claim 11, wherein the predetermined width of the second layer is 2 mm or less.

19. The heat dissipation film of claim 11, wherein the antenna pattern portion comprises a thin film antenna.

20. The heat dissipation film of claim 11, wherein the antenna pattern portion comprises at least one of a near field communication (NFC) antenna, a wireless charging antenna, or a magnetic secure transmission (MST) antenna.
